(19) United States
(12) Patent Application Publication
(10) Pub. No.: US 2005/0275073 A1
(43) Pub. Date: Dec. 15, 2005

(54) Method and system for improved wire bonding

(75) Inventors: Norihiro Kawakami, Beppu-shi (JP); Yoshikatsu Umeda, Beppu-shi (JP); Souichi Kadoguchi, Beppu-shi (JP); Hiroyuki Fujii, Higashikunisaki-gun (JP)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/864,025

(22) Filed: Jun. 9, 2004

(51) Int. Cl. H01L 23/02

(52) U.S. Cl. 257/678

(57) ABSTRACT

According to one embodiment of the invention, a method for coupling electrical contacts is provided. The method includes providing an electronic component having a contact that is to be coupled to another contact. The method also includes forming, over the contact, a bonded ball having a downwardly sloping shoulder that extends from a point and ends at an edge of the shoulder. The downwardly sloping shoulder has an angle between 105-130 degrees from a first imaginary vertical line that intersects the point. The downwardly sloping shoulder does not have a structure that makes contact with the electronic component and also extends in an outward direction from a second imaginary vertical line intersecting the edge of the shoulder. The method also includes coupling the bonded ball to the another contact using a wire.

### TECHNICAL FIELD OF THE INVENTION

This invention relates generally to electronics and more particularly to a method and system for improved wire bonding.

### BACKGROUND OF THE INVENTION

Miniaturization of integrated circuit (IC) chips is a challenged faced by most chip manufacturers. This trend towards miniaturization in turn pushes the limits of numerous high density packaging processes. An example of such a process is the wire bond process.

The wire bond process, or “wire bonding,” refers to a process of connecting electronic components and conducting tracks using a piece of wire. For example, a die may be coupled to a substrate by forming a bonded ball at each contact of the die and then looping the wire from the bonded ball to a corresponding external contact of the substrate. As the size of the contacts of the die and the substrate is reduced due to miniaturization, the size of the bonded ball may also need to be reduced. Further, wire bonding process may result in peeling and other types of pad damage because of the relatively delicate structure of miniaturized components.

### SUMMARY OF THE INVENTION

According to one embodiment of the invention, a method for coupling electrical contacts is provided. The method includes providing an electronic component having a contact that is to be coupled to another contact. The method also includes forming, over the contact, a bonded ball having a downwardly sloping shoulder that extends from a point and ends at an edge of the shoulder. The downwardly sloping shoulder has an angle between 105-130 degrees from a first imaginary vertical line that intersects the point. The downwardly sloping shoulder does not have a structure that makes contact with the electronic component and also extends in an outward direction from a second imaginary vertical line intersecting the edge of the shoulder. The method also includes coupling the bonded ball to the another contact using a wire.

Some embodiments of the invention provide numerous technical advantages. Other embodiment may realize some, none, or all of these advantages. For example, according to one embodiment, the probability of pad damage associated with wire bonding is reduced by forming a bonded ball that has a relatively flat shoulder and no flange. In another embodiment, the footprint of the bonded ball is reduced by eliminating the flange that may extend from the shoulder of the bonded ball.

Other advantages may be readily ascertainable by those skilled in the art.

### BRIEF DESCRIPTION OF THE DRAWINGS

Reference is now made to the following description taken in conjunction with the accompanying drawings, wherein like reference numbers represent like parts, in which:

FIG. 1 is a schematic diagram illustrating a wire bonding system that may benefit from the teachings of the present invention;

FIG. 2A is a diagram of a cross-sectional view of one embodiment of a bonded ball shown in FIG. 1;

FIGS. 2B and 2C are diagrams each showing a cross sectional view of one embodiment of a shoulder of the bonded ball shown in FIG. 2A;

FIG. 2D is a diagram of a cross-sectional view of one embodiment of a capillary that may be used to form the bonded ball shown in FIG. 2A; and

FIG. 3 is a flow chart illustrating one embodiment of a method of wire bonding.

### DETAILED DESCRIPTION OF EXAMPLE EMBODIMENTS OF THE INVENTION

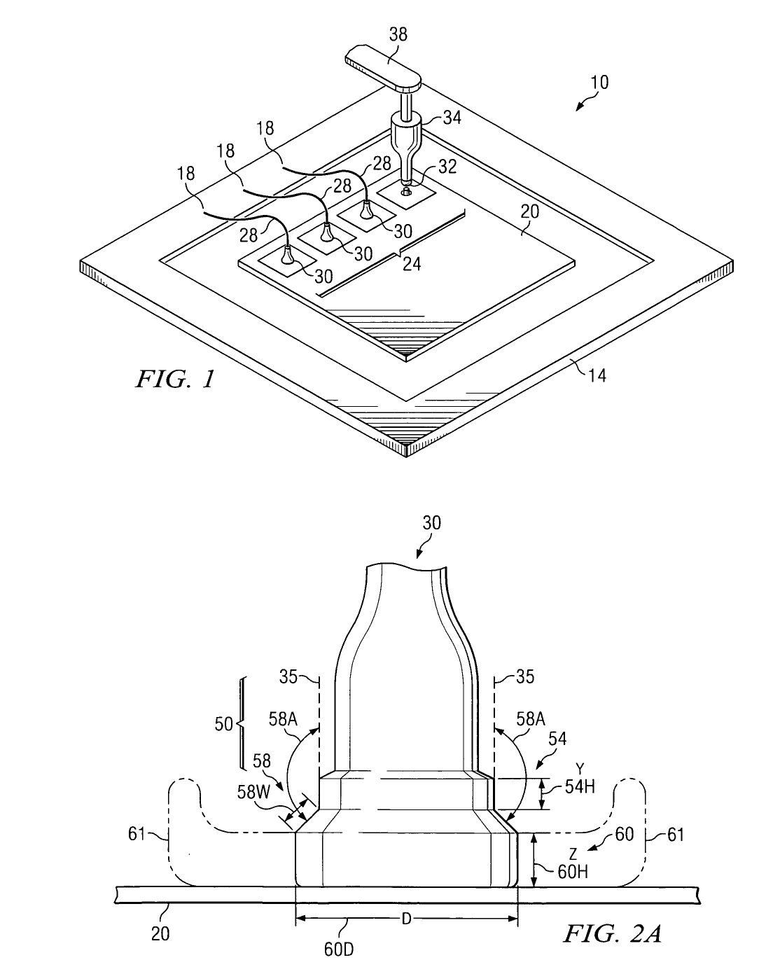

Embodiments of the invention are best understood by referring to FIGS. 1 through 3 of the drawings, like numerals being used for like and corresponding parts of the various drawings.

FIG. 1 is a schematic diagram illustrating one embodiment of a wire bonding system 10 that benefits from the teachings of the present invention. System 10 includes a substrate 14 having a plurality of contacts 18, a die 20 having a plurality of contacts 24, and a capillary 34 attached to an arm 38. A particular contact 24 of die 20 is required to be electrically coupled to a particular contact 18 of substrate 14. Contacts 24 are coupled to their respectively corresponding contacts 18 using wire strands 28 and corresponding bonded balls 30. As shown in FIG. 1, in one embodiment, bonded ball 30 has a generally circular footprint on die 20.

Capillary 34 and arm 38 are coupled to a control system (not explicitly shown in FIG. 1). The control system is operable to manipulate arm 38 and capillary 34 to couple contacts 24 and 18 by dispensing wire strands 28. This process is referred to as wire bonding.

An example of a wire bonding process is described as follows. A strand of wire is provided in capillary 34. A tip of the strand of wire is accessible through the tip of capillary 34. An electronic flame off (EFO) firing is used to form a free air ball (FAB) 32 at the tip of the wire. Capillary 34 is lowered to position FAB 32 on a particular contact 24. Then an initial ball deformation is made by applying a suitable level of bond force to form a bonded ball, such as bonded ball 30. After bonded ball 30 is formed on contact 24, capillary 34 is raised and the looping of the wire takes place as capillary 34 travels from the position of bonded ball 30 to a particular contact 18 to which the contact 24 is to be coupled. Once capillary 34 reaches the particular contact 18, a stitch is formed at the contact 18 by deforming the wire against the contact 18 to make a wedge-shaped impression. Then this wire bonding process is repeated for other contacts 24 and 18.

With the trend towards miniaturization of IC chips, the size of the contacts 18 of die 24 and substrate 14 is reduced. Thus, the size of a bonded ball may also need to be reduced. Further, the probability of damage to the pad, which is an area surrounding contact 18, may increase during the wire bonding process because smaller components tend to be more delicate. One example of damage to the pad is peeling, which refers to the removal of a layer of the pad and/or contact 18 as capillary 34 is lifted to form another wire connection.

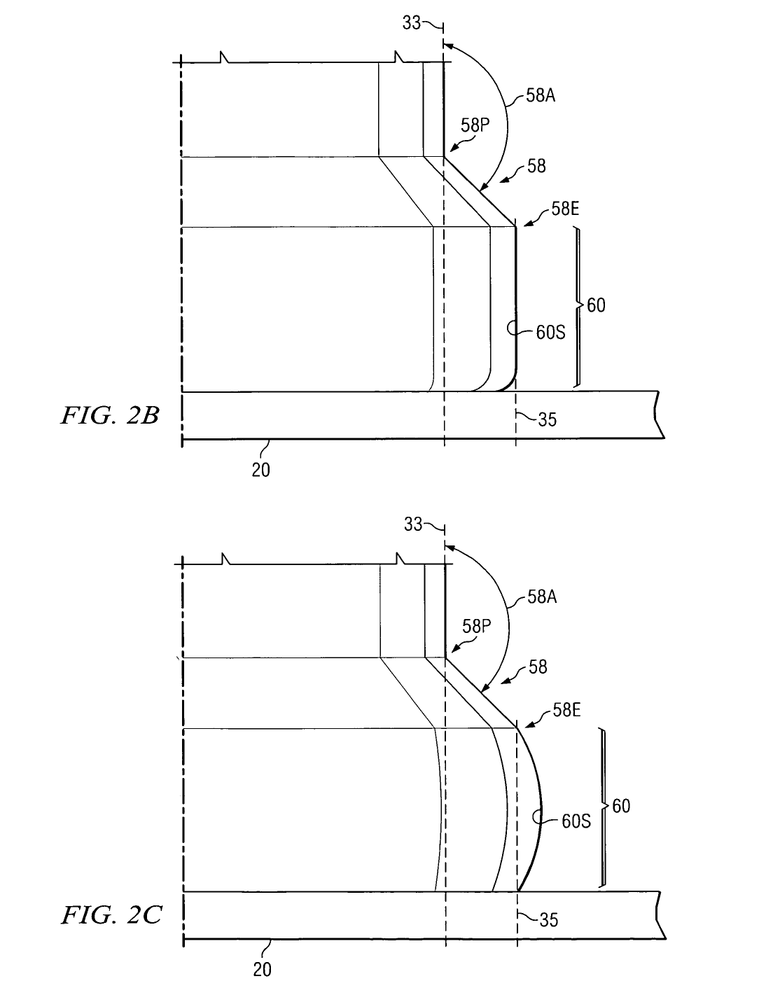

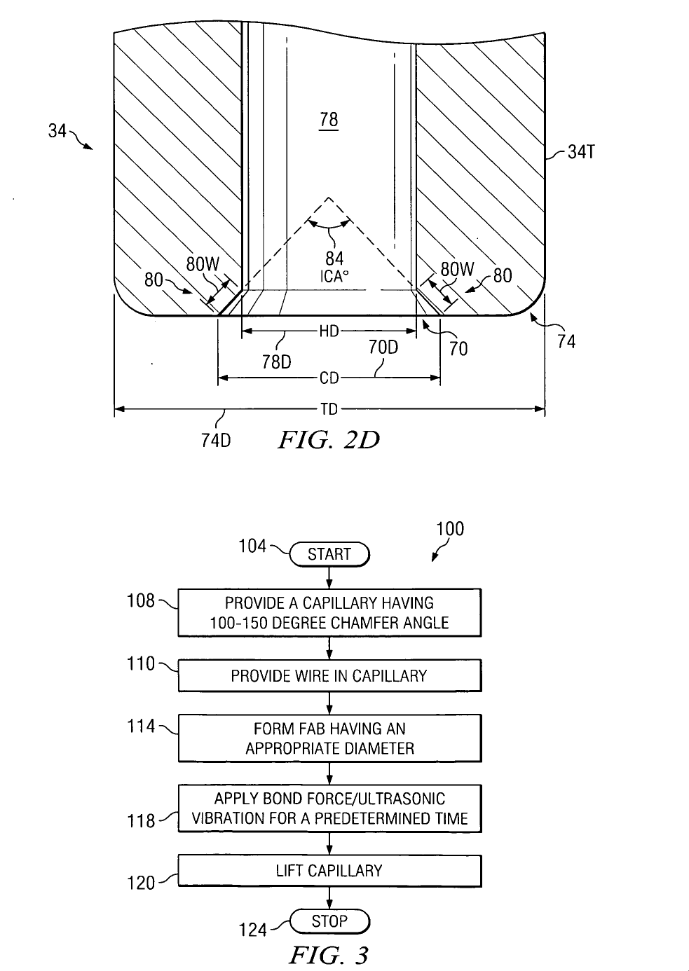

According to one embodiment of the invention, a method and system for an improved wire bonding process is provided by forming bonded ball 30 that has a downwardly-sloping shoulder at an angle of approximately 105 to 130 degrees from an imaginary vertical line and a footprint that does not extend outside of an aperture having the inner chamfer diameter of a capillary. This is advantageous in some embodiments because the probability of damage to the pad surrounding a contact is reduced. In one embodiment, this is advantageous also because the footprint of the bonded ball is reduced, which facilitates the miniaturization of electronic components. Additional details of the example embodiments of the invention are described below in greater detail in conjunction with FIGS. 2A-3.

FIG. 2A is a diagram of a side cross-sectional view of one embodiment of bonded ball 30 shown in FIG. 1. FIGS. 2B and 2C are diagrams each showing a side cross-sectional view of a shoulder 58 of bonded ball 30 shown in FIG. 2A. FIGS. 2A-2C are described jointly. Referring to FIG. 2A, bonded ball 30 includes a neck 50, a collar 54, a base 60, and shoulder 58. Collar 54 has a height 54H, a base 60 has a diameter 60D and a side 60S, and shoulder 58 has a width 58W, an angle 58A, and an edge 58E. Neck 50 is coupled to collar 54, collar 54 is coupled to shoulder 58, and shoulder 58 is coupled to base 60. In one embodiment, as shown in FIG. 1, bonded ball 30 has a generally circular footprint.

As shown in FIG. 2B, shoulder 58 begins at a point 58P and ends at an edge 58E of shoulder 58. Point 58P is located where collar 54 ends. In one embodiment where bonded ball 30 does not have collar 54, point 58P is located where neck 50 ends. Angle 58A is defined by shoulder 58 and an imaginary vertical line 33 that intersects with point 58P.

Referring back to FIG. 2A, in one embodiment, angle 58A of shoulder 58 (also referred to as shoulder angle 58) is in a range of 105 to 130 degrees, and bonded ball 30 does not have a flange 61. As shown in FIG. 2A, the absence of flange 61 is indicated by the use of phantom lines to outline flange 61. Flange 61 is described using FIG. 2B. Referring to FIG. 2B, a “flange” refers to any structure that makes contact with die 20 and also extends outwardly from an imaginary vertical line 35 that intersects with edge 58E of shoulder 58. For example, as shown in FIG. 2A, flange 61 would extend outwardly from an imaginary vertical line intersecting edge 58E and also make contact with die 20. Because flange 61 is absent, in one embodiment, side 60S of base 60 is approximately flat and does not cross imaginary vertical line 35, as shown in FIG. 2B. In one embodiment, side 60S may extend outwardly from imaginary vertical line 35 but does not make contact with die 20, as shown in FIG. 2C. Such a structure shown in FIG. 2C is not considered to be a flange.

Referring back to FIG. 2A, bonded ball 30 having shoulder 58 at angle 58A of 105-130 degrees but does not have flange 61 is advantageous in some embodiments because such a bonded ball has a smaller footprint on die 20, which promotes the miniaturization of electronic components and lowers the probability of pad damage.

In more specific embodiments, shoulder angle 58A is in a range of 105 to 115 degrees, or between 125 to 130 degrees. Forming a bonded ball using any of the above-described ranges of shoulder angle 58A, in conjunction with the elimination of a flange that extends outwardly from imaginary vertical line 35, results in a formation of a “short” shoulder 58 that reduces the probability of damage to pad area surrounding a contact, such as contact 24 shown in FIG. 1. In one embodiment, a range of 105-115 degrees for shoulder angle 58A is particularly advantageous because the range is associated with a reduced shoulder width 58W, which further reduces the probability of pad damage. In one embodiment, shoulder 58 is the only portion of bonded ball 30 that is operable to receive bond force and/or ultrasonic vibration from capillary 34 during bonded ball formation. In one embodiment, height 54H of collar 54 is shorter than height 60H of base 60. (Height 60H is also referred to as bonded ball thickness 60H). This is advantageous in some embodiments because having collar height 54H that is shorter than bonded ball thickness 60H reduces the probability of pad damage.

FIG. 2D is a diagram of a side cross-sectional view of a tip region 34T of capillary 34 that may be used to form some embodiments of bonded ball 30 shown in FIG. 2A. As shown in FIG. 2A, capillary 34 is approximately cylindrical and has varying diameters along the length. As shown in FIG. 2D, tip region 34T of capillary 34 includes a tip 74, an inner channel 78 (also referred to as a hold 78) that extends along the length of capillary 34, a chamfer 80 that extends outwardly from the end of hole 78 to tip 74, and an aperture 70 defined at tip 74 by chamfer 80. Tip 74 has a tip diameter 74D. Hole 78 has a hole diameter 78D, and chamfer 80 has a chamfer face width 80W. Aperture 70 has a diameter 70D. Diameter 70D is also referred to as an inner chamfer diameter 70D. As shown in FIG. 2D, inner chamfer diameter 70D is greater than hole diameter 78D because chamfer 80 extends outwardly from hole 78. Chamfer 80 extends outwardly from hole 78 at an inner chamfer angle 84. Inner chamfer angle 84 is measured between opposing portions of chamfer 80, as shown using phantom lines in FIG. 2D.

In one embodiment, inner chamfer angle 84 is in a range of 100 to 150 degrees, with particularly suitable ranges being between 100 to 110 degrees and 130 to 150 degrees. The above-identified ranges are advantageous in some embodiments because a bonded ball resulting from using a capillary having such inner chamfer angles will have a “short” shoulder that reduces the possibility of pad damage. In one embodiment, chamfer diameter 70D may be 42 micrometers or less, and hole diameter 78D may be 32 micrometers or less.

Referring to FIGS. 2A and 2D, in one embodiment, angle 58A of shoulder 58 is in a range of 105 to 130 degrees (which results from forming shoulder 58 with capillary 34 having inner chamfer angle 84 in the range of 100-150 degrees), and diameter 60D of base 60 is equal to or less than chamfer diameter 70D of capillary 34 used to form bonded ball 30. In another embodiment where side 60S of base 60 is not flat, as shown in FIG. 2C, diameter 60D of base 60 measured at the surface that makes physical contact with die 20 is equal to or less than chamfer diameter 70D.

In some embodiments, one skilled in the art may form a bonded ball having a shoulder at an angle between 105-130 degrees and no flange, such as bonded ball 30 shown in FIG. 2A, by providing a wire having a suitable diameter in a capillary, such as capillary 34, forming a free air ball having a suitable diameter, and applying a suitable level and type of bond force for a suitable length of time. The type/diameter of the wire, the diameter of the free air ball, the level of bond force, and the bond force time period may be optimized based on particular design specifications by one skilled in the art to form different embodiments of a bonded ball of the present invention. One example process of forming one embodiment of bonded ball 30 is described below in conjunction with FIG. 3.

FIG. 3 is a flow chart illustrating one embodiment of a method 100 for improved wire bonding. One embodiment of method 100 is described using capillary 34 shown in FIG. 2D and bonded ball 30 shown in FIG. 2A. However, any suitable device or a combination of devices may be used to implement method 100.

Method 100 starts at step 104. At step 108, a capillary having a chamfer angle of approximately 100 to 150 degrees is provided. An example of the capillary of step 108 is capillary 34; however, any suitable device may be used. At step 110, wire is provided in capillary 34. The wire may be formed from gold, aluminum, copper, or any other suitable material. In one embodiment, the diameter of the wire is less than 25 micrometers. However, other wire diameters may be used depending on the particular requirements for the wire bonding process and hole diameter 78D of capillary 34.

At step 114, a free air ball is formed at the tip of the wire provided at step 110. Example diameters of the free air ball include, but are not limited to, 85-115 percent, 90-110 percent, and 92-108 percent of chamfer diameter 70D (shown in FIG. 2D). In some embodiments, the diameter of the free air ball is different from chamfer diameter 70 by 2 micrometers or less. Any suitable diameter for forming a bonded ball having no flange may be used as a free air ball diameter of step 114.

At step 118, bond force is applied on free air ball for a predetermined period of time. In one embodiment, a bond force of 20 gram-force is applied for 10 milliseconds or less; however, any suitable level of bond force may be applied for any suitable length of time, depending on the design specifications of bonded ball 30. In conjunction with the applied bond force, ultrasonic vibration may also be provided to enhance the formation of bonded ball 30. In one embodiment, bond force and/or ultrasonic vibration is applied only through chamfer face 80. At step 120, capillary is lifted for the looping of the wire. Method 100 stops at step 124.

Although some embodiments of the present invention have been described in detail, it should be understood that various changes, substitutions, and alterations can be made hereto without departing from the spirit and scope of the invention as defined by the appended claims.

1. A method for coupling electrical contacts, comprising:
providing a capillary having an inner channel and a tip, the inner channel disposed along the length of the capillary and extending toward the tip, a portion of the inner channel flaring outwardly to form an inner chamfer that defines an aperture having an inner chamfer diameter at the tip of the capillary, wherein the inner chamfer has an inner chamfer face, and a first portion of the inner chamfer face and a second portion of the inner chamfer face positioned opposite from the first portion together define an inner chamfer angle in a range between 100-150 degrees;
providing a wire in the inner channel, the wire having a wire tip that is accessible through the aperture;
forming a free air ball using the wire tip, the free air ball having a diameter between 90 percent and 110 percent of the inner chamfer diameter;
positioning the free air ball over an electrical contact of a die;
after positioning the free air ball, applying, through the inner chamfer face, a bond force of 20 gram-force or less on the free air ball for a time period of ten milliseconds or less; and
after the time period, lifting the capillary from the electrical contact, leaving on the electrical contact a bonded ball including a neck, a downwardly sloping shoulder extending from the neck at an angle between 105 and 130 degrees from an imaginary vertical axis, and a base, the neck and the shoulder overlying all of an area of the base that makes contact with the die.

2. The method of claim 1, wherein the area of the bonded ball that makes contact with the die does not have a physical dimension that exceeds the inner chamfer diameter.

3. The method of claim 1, wherein the bonded ball does not include a flange that extends from the base.

4. The method of claim 1, wherein the wire comprises a wire diameter equal to or less than 25 micrometers.

5. A method for coupling electrical contacts, comprising;
providing an electronic component having a contact that is to be coupled to another contact;
forming, over the contact, a bonded ball having a downwardly sloping shoulder that extends from a point and ends at an edge of the shoulder, the downwardly sloping shoulder having an angle between 105-130 degrees from a first imaginary vertical line that intersects the point but being absent a structure that makes contact with the electronic component and also extends in an outward direction from a second imaginary vertical line intersecting the edge; and
coupling the bonded ball to the another contact using a wire.

6. The method of claim 5, wherein the wire comprises a diameter equal to or less than 25 micrometers.

7. The method of claim 5, wherein the wire has a diameter less than 25 micrometers, and wherein forming a bonded ball comprises:
providing the wire in a capillary having an inner chamfer diameter; and
forming the bonded ball from a free air ball having a diameter that is different from the inner chamfer diameter by two micrometers or less.

8. The method of claim 5, wherein forming a bonded ball comprises:
providing the wire in a capillary having an inner chamfer diameter; and
forming the bonded ball from a free air ball having a diameter that is 92-108 percent of the inner chamfer diameter.

9. The method of claim 5, wherein forming a bonded ball comprises forming the bonded ball using a bond force equal to or less than 20 gram-force, the bond force applied only to the shoulder.

10. The method of claim 5, wherein forming a bonded ball comprises forming the bonded ball by applying a bond force equal to or less than 20 gram-force for ten milliseconds or less.

11. The method of claim 5, wherein the wire is dispensed from a capillary having an inner chamfer diameter, and wherein forming a bonded ball comprises forming a free air ball at a tip of the wire, the free air ball having a diameter that is different from the inner chamfer diameter by two micrometers or less.

12. The method of claim 5, wherein the bonded ball comprises a neck, a collar, and a base, the neck connected to the collar, the collar connected to the shoulder, and the shoulder connected to the base, the collar having a first height that is shorter than a second height of the base.

13. The method of claim 5, wherein forming a bonded ball comprises forming the bonded ball using a capillary having a tip that defines an aperture, the aperture having an inner chamfer diameter, and wherein the bonded ball does not have a flange that extends outside of an imaginary vertical cylinder that is parallel to a center axis of the capillary and intersects with the boundary of the aperture.

14-20. (canceled)
